(19) United States
(12) Patent Application Publication
(10) Pub. No.: US 2018/0342543 A1
(43) Pub. Date: Nov. 29, 2018

(54) BACKSIDE ILLUMINATED CMOS IMAGE SENSOR AND METHOD OF FABRICATING THE SAME

(71) Applicant: WUHAN XINXIN SEMICONDUCTOR MANUFACTURING CO., LTD., Wuhan (CN)

(72) Inventors: Yanyun LIU, Wuhan (CN); Jinwen DONG, Wuhan (CN); Yang FU, Wuhan (CN); Jifeng ZHU, Wuhan (CN)

(21) Appl. No.: 15/962,377

(22) Filed: Apr. 25, 2018

(30) Foreign Application Priority Data
May 27, 2017 (CN) 201710390933.X

(51) Int. Cl. H01L 27/146

(52) U.S. Cl. CPC H01L 27/1464; H01L 27/14636; H01L 27/14685; H01L 27/14621; H01L 27/14627; H01L 27/14634

(57) ABSTRACT

A backside illuminated CMOS image sensor and a method of fabricating the sensor are disclosed. The backside illuminated CMOS image sensor includes a first substrate and a second substrate. A plurality of pixel cells are formed in the front side of the first substrate, and a plurality of grooves are formed in the back side. Each of the grooves has at least one sidewall inclined with respect to the back surface of the first substrate. The second substrate is bonded to the first substrate on a side closer to the front side. A method for fabricating such a backside illuminated CMOS image sensor is also disclosed. The grooves formed in the back side of the first substrate can reduce reflection loss of light incident on the back surface and hence enhance quantum efficiency of the backside illuminated CMOS image sensor.

### CROSS-REFERENCES TO RELATED APPLICATIONS

This application claims the priority of Chinese patent application number 201710390933.X, filed on May 27, 2017, the entire contents of which are incorporated herein by reference.

### TECHNICAL FIELD

The present invention relates to the field of image sensors and, in particular, to a backside illuminated CMOS image sensor and a method of fabricating the same.

### BACKGROUND

Integrated circuit (IC) technology has brought tremendous changes in many fields including computers, control systems, communication and images. In the field of images, image sensors are used as important components of digital cameras. Image sensors can be classified into charge coupled device (CCD) image sensors and complementary metal oxide semiconductor (CMOS) image sensors, depending on the photosensitive elements that they use and how light is sensed. Compared with CCD image sensors, CMOS image sensors can better address the ever-increasing demand of various user applications for higher image sensor performance, including, for example, more flexible image capturing, higher sensitivity, a wider dynamic range, a higher resolution, lower power consumption, better system integration, etc.

In general terms, CMOS image sensors are grouped into front-illuminated and back-illuminated. In a frontside illuminated CMOS image sensor, light is incident on a front side of the sensor, passes through an interlayer dielectric layer and interconnect layers and ultimately reaches photodiodes in pixel elements. However, additional layers (e.g., opaque layers and reflective metal layers) in the path of the light will limit the portion of the light that reaches the photodiodes, leading to impaired quantum efficiency. In contrast, in case of a backside illuminated CMOS image sensor, the light is incident on a back side of the sensor and reaches the photodiodes, without passing through the interlayer dielectric layer and interconnect layers. This allows a direct access of the light to the photodiodes, which significantly improves the image quality by reducing loss of the light and increasing optical energy acquired by each single pixel element per unit time. Nevertheless, according to findings in research conducted by the applicant, photoelectric conversion efficiency of conventional backside illuminated CMOS image sensors is still unsatisfactory and their quantum efficiency is relatively low.

### SUMMARY OF THE INVENTION

It is an objective of the present invention to improve the quantum efficiency of backside illuminated CMOS image sensors.

This objective is attained by a backside illuminated CMOS image sensor and a method of fabricating such a sensor, proposed in the present invention.

The proposed backside illuminated CMOS image sensor includes:

a first substrate having a front side with a plurality of pixel cells formed therein and a back side with a plurality of grooves formed therein, each of the plurality of grooves having at least one sidewall inclined with respect to a back surface of the first substrate; and

a second substrate boned to the first substrate on a side closer to the front side of the first substrate.

Optionally, the backside illuminated CMOS image sensor may further include an interlayer dielectric layer and interconnect layers formed over the front side of the first substrate, the interlayer dielectric layer covering a front surface of the first substrate, the interconnect layers formed in the interlayer dielectric layer.

Optionally, the backside illuminated CMOS image sensor may further include a planarization layer covering the back surface of the first substrate and filling the plurality of grooves, a color filter layer covering the planarization layer and a lens layer covering the color filter layer, the color filter layer including a plurality of color filter cells, the lens layer including a plurality of micro-lenses, wherein the plurality of color filter cells, as well as the plurality of micro-lenses, are in one-to-one correspondence with the plurality of pixel cells along a direction perpendicular to the back surface of the first substrate.

Optionally, the first substrate and the second substrate may be bonded together by means of a first bonding layer on the first substrate and a second bonding layer on the second substrate.

Optionally, the plurality of grooves may have cross sections, taken along a direction perpendicular to the back surface of the first substrate, assuming one or more shapes selected from the group consisting of a V-like shape, a W-like shape and a trapezoidal shape, and cross sections, taken along a direction parallel to the back surface of the first substrate, assuming one or more shapes selected from the group consisting of a circular shape, an elliptical shape, a cross-like shape and a polygonal shape.

Optionally, the grooves may be uniformly distributed on the back side of the first substrate and equally sized.

Optionally, each of the pixel cells may be in positional correspondence with one or more of the plurality of the grooves in the back side of the first substrate.

The present invention also provides a method of fabricating the backside illuminated CMOS image sensor as defined above, including:

providing a first substrate having a front side with a plurality of pixel cells formed therein and a back side;

providing a second substrate;

bonding the second substrate to the first substrate on a side closer to the front side of the first substrate; and

forming a plurality of grooves in the back side of the first substrate, each of the plurality of grooves having at least one sidewall inclined with respect to a back surface of the first substrate.

Optionally, prior to the formation of the plurality of the grooves in the back side of the first substrate, the first substrate may be thinned at the back surface.

Optionally, the plurality of the grooves may be formed in the back side of the first substrate using a dry or wet etching process.

Optionally, subsequent to the formation of the plurality of the grooves in the back surface of the first substrate, a planarization layer covering the back surface of the first substrate and filling the grooves, a color filter layer residing on the planarization layer and a lens layer residing on the color filter layer may be sequentially formed, wherein the color filter layer includes a plurality of color filter cells, wherein the lens layer includes a plurality of micro-lenses and wherein the color filter cells, as well as the micro-lenses, are in one-to-one correspondence with the pixel cells along a direction perpendicular to the back surface of the first substrate.

As noted above, the present invention proposes a backside illuminated CMOS image sensor and a method of fabricating the sensor. The backside illuminated CMOS image sensor includes a first substrate having a front side and a back side. A plurality of pixel cells are formed in the front side and the second substrate is boned to the first substrate on a side closer to the front side. A plurality of grooves are formed in the back side of the first substrate, each having at least one sidewall inclined with respect to a back surface of the first substrate. Upon incidence of light into the grooves, it will experience one or more reflections before reaching the pixel cells. Compared with a flat back surface, the introduction of the grooves can expand the light-incidence area and increase, to a certain extent, the number of reflections of the light at the back surface of the first substrate, thereby augmenting the portion of the light that reaches the pixel cells. As a result, quantum efficiency is improved over the conventional backside illuminated CMOS image sensors.

### BRIEF DESCRIPTION OF THE DRAWINGS

FIG. 1 is a schematic cross-sectional view of a backside illuminated CMOS image sensor according to an embodiment of the present invention.

FIGS. 2a to 2c are schematic cross-sectional views of three types of grooves that may be formed in backside illuminated CMOS image sensors in accordance with embodiments of the present invention.

FIGS. 3a and 3b are schematic top views of backside illuminated CMOS image sensors according to embodiments of the present invention, showing their different light-incident surfaces.

FIGS. 4a to 4d are schematic cross-sectional views showing a process of fabricating a backside illuminated CMOS image sensor in accordance with an embodiment of the present invention.

### In these figures:

10—first substrate; 20—second substrate; 10a—front surface of the first substrate; 10b—back surface of the first substrate; 11—recess; 12—shallow trench isolation (STI); 13—interlayer dielectric layer; 14—interconnect layer; 15—planarization layer; 16—color filter layer; 17—lens layer; 101—first bonding layer; and 201—second bonding layer.

### DETAILED DESCRIPTION

In order for the objectives, features, and advantages of the present invention to be more readily understood, the invention will be described below in greater detail by way of specific examples with reference to the accompanying drawings.

As used in the specification and claims, the terms “first”, “second” and the like are meant to distinguish similar elements from each other rather than necessarily indicate specific sequential or temporal orderings. It is to be understood that the terms so used are interchangeable under appropriate circumstances such that the embodiments of the invention described herein are, for example, capable of operation in other orientations than those illustrated or otherwise described herein. Likewise, if any method described herein includes a sequence of steps, then the order of the steps presented herein does not have to be the only order in which the steps may be performed, and some of the steps may be omitted and/or some other steps not described herein may be added to the method. If any element in an embodiment of the present invention depicted in one of the accompanying drawings is identical to that in another one or other ones of the drawings, for the sake of clarity, a reference numeral for the element may not be marked in all of these figures even if the element is readily identifiable therein.

Quantum efficiency of a backside illuminated CMOS image sensor generally refers to the ratio of the number of generated electrons to the number of photons that struck a back side of the sensor. In research conducted by the applicant, it has been found that light bound to a backside illuminated CMOS image sensor will be partially reflected away at a back surface of a substrate in which the sensor is formed before its arrival at the sensor, which impairs the photoelectric conversion efficiency and hence quantum efficiency of the sensor.

Based on this finding, the present invention provides a backside illuminated CMOS image sensor including a first substrate having a back side in which a number of grooves are formed each having at least one sidewall inclined with respect to a back surface of the first substrate. Upon incidence of light into the grooves, it will be reflected once or more times and then reaches pixel cells in the sensor. The grooves expand the light-incidence area of the back surface of the first substrate and increase to a certain extent reflections of the light thereat, thereby reducing reflection loss of the light and increasing the portion thereof reaching the pixel cells. This allows higher quantum efficiency over the conventional backside illuminated CMOS image sensors.

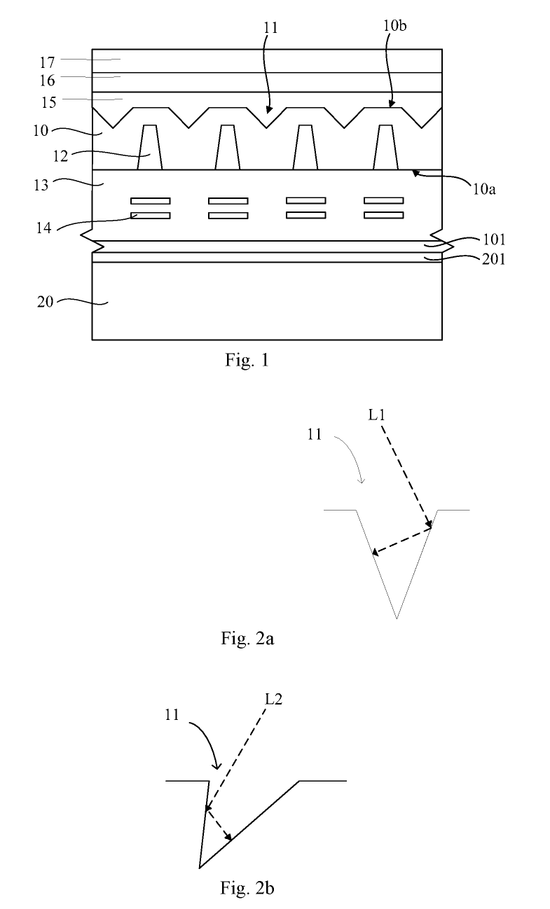

FIG. 1 is a schematic cross-sectional view of a backside illuminated CMOS image sensor according to an embodiment of the present invention. As shown in FIG. 1, the backside illuminated CMOS image sensor includes a first substrate 10 having a front surface 10a and a back surface 10b opposing the front surface. A plurality of grooves 11 are formed in the back surface 10b, each of which has at least one sidewall inclined with respect to the back surface 10b. The backside illuminated CMOS image sensor also includes a second substrate 20 boned to the first substrate 10 from the side closer to the front surface 10a.

In FIG. 1, the backside illuminated CMOS image sensor is depicted with the front surface 10a facing downward. Light is incident on pixel cells from the side closer to the back surface 10b. Specifically, the first substrate 10 and the second substrate 20 may be silicon, germanium, silicon germanium (SiGe), gallium arsenide (GaAs) or silicon-on-insulator (SOI) substrates. A person skilled in the art can choose a substrate according to the need.

With continued reference to FIG. 1, a plurality of pixel cells (or pixel units) are formed in the front side of the first substrate 10. Adjacent pixel cells are separated from each other by shallow trench isolations (STIs) 12 and an interlayer dielectric layer 13. Each of the pixel cells can include, for example, a photodiode and a plurality of MOS transistors (not shown in FIG. 1) serving as a drive circuit. Usually, each single pixel cell may be a 3T (3-transistor) or 4T (4-transistor) structure. Moreover, the interlayer dielectric layer 13 may cover the front surface 10a and the pixel cells, and multilayer interconnect layers 14 may be formed in the interlayer dielectric layer 13. Each of the interconnect layers 14 may include a plurality of stacked interconnect metal layers and spacers (not shown) for connecting adjacent interconnect metal layers. During the fabrication of the pixel cells, peripheral circuitry may be formed on the front surface 10a of the first substrate 10, and the interconnect layers 14 may be used for electrical connection of the photodiodes, the drive circuits and the peripheral circuitry. Each of the photodiodes may receive an optical signal and convert it into an electrical signal, and the electrical signal may then be transmitted to the drive circuit and further transmitted to the peripheral circuitry by the drive circuit.

The second substrate 20 may be boned to the first substrate 10 on the side closer to the front surface 10a. The bonding may be accomplished by means of a first bonding layer 101 on the interlayer dielectric layer 13 and a second bonding layer 201 on the second substrate 20. The first bonding layer 101 and the second bonding layer 201 may be silicon dioxide (SiO₂) or another material.

With continued reference to FIG. 1, a plurality of grooves 11 are formed in the back surface 10b of the first substrate 10, each having at least one sidewall inclined with respect to the back surface 10b. In a preferred embodiment, in order to mitigate the first substrate 10 from weakening the incident light on the side closer to the back surface 10b, the first substrate 10 may be thinned at the back surface 10b prior to the formation of the grooves 11, with the second substrate 20 used as a support in the subsequent processes.

In a preferred embodiment, a planarization layer 15 may be formed to cover the back surface 10b of the first substrate 10 and fills the grooves 11 to protect and planarize the back surface 10b in which the grooves 11 are formed. The planarization layer 15 may be selected as a material that allows good transmission of the incident light and less absorb or reflect it, such as SiO₂, so as to reduce its reflection and absorption losses. In addition, on the side closer to the back surface 10b are further formed a color filter layer 16 and a lens layer 17 so that the color filter layer 16 resides on the planarization layer 15 and the lens layer 17 resides on the color filter layer 16. The color filter layer 16 may include a plurality of color filter cells (e.g., light filters) each only allowing a component of the incident light of a certain color to pass through. The lens layer 17 may include a plurality of micro-lenses capable of optical condensation. For accurate capture of the incident light, the color filter cells, as well as the micro-lenses, may be in one-to-one correspondence with the pixel cells in the direction perpendicular to the back surface 10b of the first substrate 10. In other embodiments, subsequent to the formation of the planarization layer 15 and prior to the formation of the color filter layer 16, transparent electrodes (not shown) may be further formed on the planarization layer 15 which are electrically connected to the respective drive circuits to transmit the electrical signals to the peripheral circuitry. The electrodes may be formed of a transparent conductive oxide or aluminum.

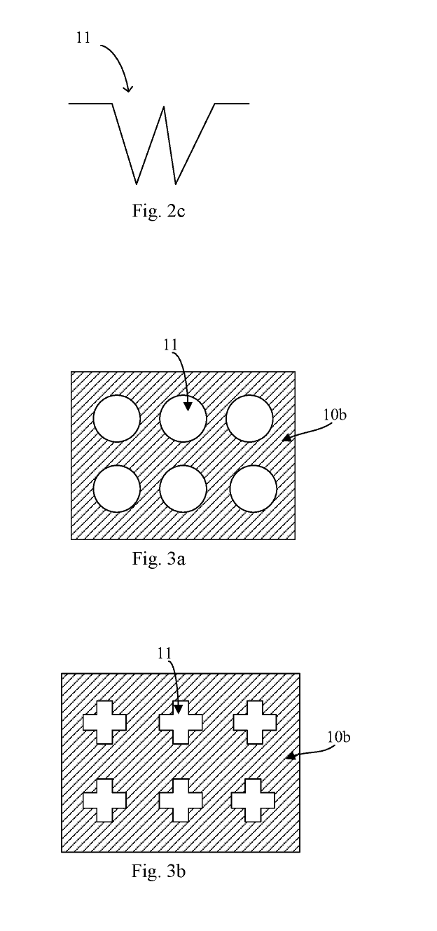

FIGS. 2a to 2c are schematic cross-sectional views of three types of grooves that may be formed in a backside illuminated CMOS image sensor in accordance with an embodiment of the present invention. The recess 11 of FIG. 2a has a V-shaped cross section taken along the direction perpendicular to the back surface 10b of the first substrate 10 and two sidewalls symmetrical to each other with respect to a central axis of the V-shape. The recess 11 of FIG. 2b also has a V-shaped cross section taken along the direction perpendicular to the back surface 10b of the first substrate 10 and two asymmetrical sidewalls. When a light beam L1 is incident into the recess 11 of FIG. 2a, or when a light beam L2 is incident into the recess 11 of FIG. 2b, the light beam will experience multiple refractions and reflections before it reaches the pixel cells due to the at least one sidewall inclined with respect to the back surface 10b. Compared to a flat back surface, the introduction of the grooves 11 may expand the light-incidence area and reduce, to a certain extent, the portion of the light reflected away (due to possible re-incidence of the reflected portions). As a result, the amount of received light per pixel cell and hence the quantum efficiency of the backside illuminated CMOS image sensor is increased. The cross-sectional shapes of the grooves 11 along the direction perpendicular to the back surface 10b of the first substrate 10 are not limited to those according to the embodiments shown in FIGS. 2a and 2b, as they may also be a W-like shape as shown in FIG. 2c, a trapezoidal shape or any combination of the V-like, W-like and trapezoidal shapes.

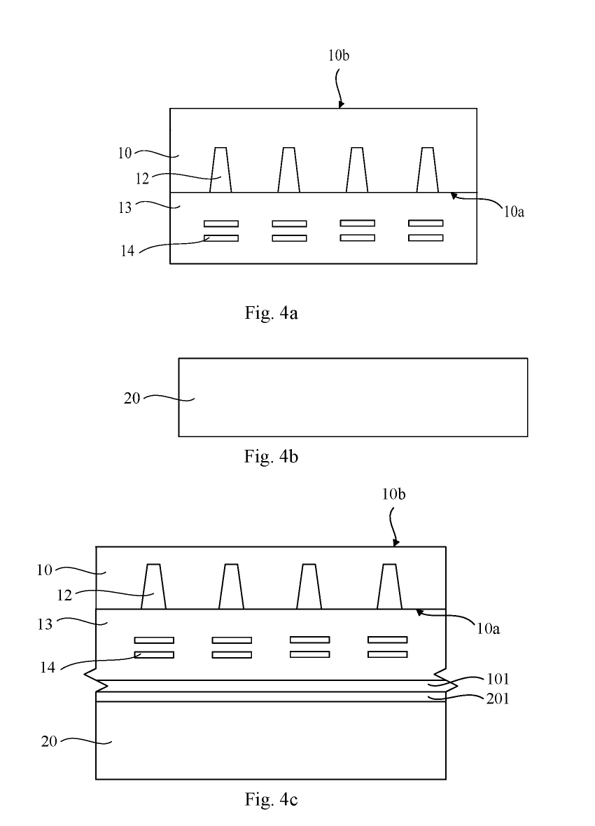

FIGS. 3a and 3b are schematic top views of backside illuminated CMOS image sensors according to embodiments of the present invention, showing their different light-incident surfaces. In the embodiment shown in FIG. 3a, the grooves are uniformly distributed on the back surface 10b of the first substrate 10 and appear as circles when seen from the top view. In the embodiment shown in FIG. 3b, the grooves are uniformly distributed on the back surface 10b of the first substrate 10 and appear as crosses when seen from the top view. In one embodiment, the grooves 11 are conical grooves each having a V-shaped cross section as shown in FIG. 2a and appearing as a circle when seen from the top view. In other embodiments of the present invention, the grooves 11 may assume shapes with different appearances when seen from the top view, for example, ellipses, crosses, polygons or any combination thereof. In addition, the number of the grooves 11 in the back surface 10b of the first substrate 10 is greater than one, and each of the pixel cells may correspond to one or more of them. The grooves 11 may have the same shape or different shapes in the direction parallel to the back surface 10b of the first substrate 10.

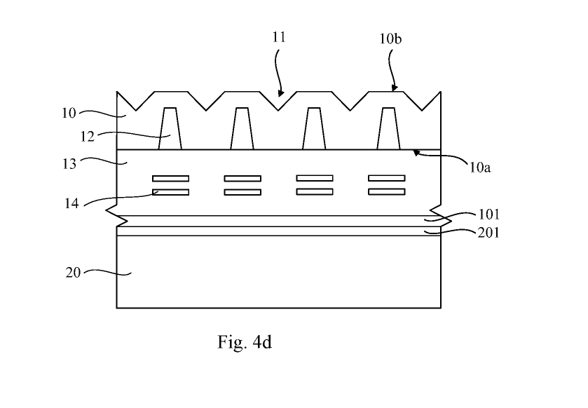

A method for fabricating a backside illuminated CMOS image sensor according to an embodiment of the present invention will be described in detail below with reference to FIGS. 4a to 4d and FIG. 1.

At first, as shown in FIG. 4a, a first substrate 10 having a front surface 10a and a back surface 10b is provided. A plurality of pixel cells are formed in the front side of the first substrate, and adjacent pixel cells are separated from each other by shallow trench isolations (STIs) 12 and an interlayer dielectric layer 13. Additionally, interconnect layers 14 are formed in the interlayer dielectric layer 13. Specifically, the formation of the pixel cells may include, for example, the steps of: forming gates of MOS transistors on the front surface 10a of the first substrate 10 and gate dielectric layers under the gates; and forming first doped regions in portions of the first substrate 10 close to the gates. The doping type of the first doped regions may be opposite to that of the first substrate 10. For example, the first substrate 10 may be P-doped with the first doped regions being N-doped, or vice versa. As such, PN junctions are formed between the first doped regions and the first substrate 10 along the direction perpendicular to the front surface 10a of the first substrate 10 such that photodiodes are formed. The first-substrate parts of the photodiodes receive the incident light which then causes current variations in the photodiodes, converting the optical signals into electrical signals. Sources and drains of the MOS transistors may be fabricated in the same step as the first doped regions to save process steps and reduce the fabrication cost. It will be appreciated that the pixel cells, the STIs, the interlayer dielectric layer 13 and the interconnect layers 14 may be fabricated using processes known in the art. While not specified in further detail herein, they are considered to be known to those skilled in the art.

Subsequently, as shown FIG. 4b, a second substrate 20 is provided. After that, as shown in FIG. 4c, the second substrate 20 is bonded to the first substrate 10 on the side closer to the front surface 10a. Specifically, the bonding may include: forming a first bonding layer 101 on the interlayer dielectric layer 13; forming a second bonding layer 201 on the second substrate 20; and directly bonding the first bonding layer 101 and the second bonding layer 201 together in vacuum. The first bonding layer 101 and the second bonding layer 201 may be formed of silicon dioxide (SiO₂) or another material. It is a matter of course that the first substrate 10 and the second substrate 20 may also be bonded together using any other applicable process in the field of semiconductor technology than vacuum bonding.

Afterward, as shown in FIG. 4d, a plurality of grooves 11 are formed in the back surface 10b of the first substrate 10, each has at least one sidewall inclined with respect to the back surface 10b. Specifically, the number and shape of the grooves 11 may be determined depending on the process conditions and practical needs. Additionally, the number of grooves 11 corresponding to each pixel cell may also vary. For example, it is possible to form only one large recess 11 or a plurality of small grooves 11 for each pixel cell. Further, the slant and depth of the grooves 11 may be properly designed so as to allow the backside illuminated CMOS image sensor to have desired performance. The grooves 11 may be formed in the back surface 10b of the first substrate 10 using a dry etching process with properly designed parameters such as etching direction, etching rate and etching gas ratio or a wet etching process with properly designed parameters such as etching solution concentration and etching time. A person skilled in the art will know how to form the grooves from the disclosure of the present application and the common knowledge in the art, and the present invention is not limited in any specific method of formation.

In a preferred embodiment, prior to the formation of the plurality of grooves 11 in the back surface 10b of the first substrate 10, the first substrate 10 may be thinned at the back side.

Thereafter, as shown in FIG. 1, a planarization layer 15 is formed which covers the back surface 10b of the first substrate 10 and fills the grooves 11 to protect and planarize the back surface 10b in which the grooves 11 are formed. This is followed by formation of transparent electrodes on the planarization layer 15 and subsequent sequential formation of a color filter layer 16 on the transparent electrodes and a lens layer 17 on the color filter layer 16.

It is noted that the foregoing embodiments are described in a progressive manner, with the emphasis being placed on differences therebetween. Reference can be made between the embodiments for their similarities and differences. As the disclosed methods correspond to the disclosed devices, they are described in a simplified manner, and reference can be made to the description of the device for relevant details.

The preferred embodiments presented above are merely examples and are in no way meant to limit the present invention. Possible modifications and variations may be made to the subject matter of the present invention by those skilled in the art based on the above teachings without departing from the scope of the present invention. Accordingly, any simple variations, equivalent changes and modifications made to the foregoing embodiments based on the substantive disclosure of the present invention without departing from the scope of the present invention fall within the scope thereof.

What is claimed is:

1. A backside illuminated CMOS image sensor, comprising:
a first substrate having a front side with a plurality of pixel cells formed therein and a back side with a plurality of grooves formed therein, each of the plurality of grooves having at least one sidewall inclined with respect to a back surface of the first substrate; and
a second substrate boned to the first substrate to the front side of the first substrate.

2. The backside illuminated CMOS image sensor of claim 1, further comprising an interlayer dielectric layer and interconnect layers formed over the front side of the first substrate, the interlayer dielectric layer covering a front surface of the first substrate, the interconnect layers formed in the interlayer dielectric layer.

3. The backside illuminated CMOS image sensor of claim 2, wherein the first substrate and the second substrate are bonded together by means of a first bonding layer on the first substrate and a second bonding layer on the second substrate.

4. The backside illuminated CMOS image sensor of claim 1, further comprising a planarization layer covering the back surface of the first substrate and filling the plurality of grooves, a color filter layer covering the planarization layer and a lens layer covering the color filter layer, the color filter layer comprising a plurality of color filter cells, the lens layer comprising a plurality of micro-lenses, wherein the plurality of color filter cells, as well as the plurality of micro-lenses, are in one-to-one correspondence with the plurality of pixel cells along a direction perpendicular to the back surface of the first substrate.

5. The backside illuminated CMOS image sensor of claim 1, wherein the plurality of grooves have cross sections, taken along a direction perpendicular to the back surface of the first substrate, assuming one or more shapes selected from the group consisting of a V-like shape, a W-like shape and a trapezoidal shape, and cross sections, taken along a direction parallel to the back surface of the first substrate, assuming one or more shapes selected from the group consisting of a circular shape, an elliptical shape, a cross-like shape and a polygonal shape.

6. The backside illuminated CMOS image sensor of claim 5, wherein the plurality of grooves are uniformly distributed on the back side of the first substrate and are equally sized.

7. The backside illuminated CMOS image sensor of claim 6, wherein each of the plurality of pixel cells is in positional correspondence with one or more of the plurality of the grooves in the back side of the first substrate.

8. A method of fabricating the backside illuminated CMOS image sensor as defined in claim 1, comprising:
providing a first substrate having a front side with a plurality of pixel cells formed therein and a back side;
providing a second substrate;
bonding the second substrate to the first substrate on a side closer to the front side of the first substrate; and
forming a plurality of grooves in the back side of the first substrate, each of the plurality of grooves having at least one sidewall inclined with respect to a back surface of the first substrate.

9. The method of claim 8, further comprising thinning the back side of the first substrate prior to forming the plurality of the grooves in the back side of the first substrate.

10. The method of claim 8, wherein the plurality of the grooves are formed in the back side of the first substrate using a dry or wet etching process.

11. The method of claim 8, further comprising, subsequent to forming the plurality of the grooves in the back side of the first substrate:
forming a planarization layer covering the back surface of the first substrate and filling the plurality of grooves;
forming a color filter layer covering the planarization layer; and
forming a lens layer covering the color filter layer, the color filter layer comprising a plurality of color filter cells, the lens layer comprising a plurality of micro-lenses, and wherein the plurality of color filter cells, as well as the plurality of micro-lenses, are in one-to-one correspondence with the plurality of pixel cells along a direction perpendicular to the back surface of the first substrate.
